(19) United States
(12) Patent Application Publication
(10) Pub. No.: US 2026/0164899 A1
(43) Pub. Date: Jun. 11, 2026

(54) MICRO LED STRUCUTRE

(71) Applicant: JADE BIRD DISPLAY (SHANGHAI) LIMITED, SHANGHAI (CN)

(72) Inventor: Shuang ZHAO, Shanghai (CN)

(21) Appl. No.: 19/178,919

(22) Filed: Apr. 15, 2025

(30) Foreign Application Priority Data
Apr. 16, 2024 (WO) PCT/CN2024/087926

(51) Int. Cl. H10H 29/855

(52) U.S. Cl. CPC H10H 29/855

(57) ABSTRACT

A micro LED structure includes a micro mesa comprising a bottom electrode, a PN junction structure, and a top electrode from bottom to top; and a micro lens formed on the micro mesa, wherein a top surface of the micro lens comprises a sub-micro lens array comprising a plurality of sub-micro lenses.

### CROSS-REFERENCE TO RELATED APPLICATIONS

The present disclosure claims the benefits of priority to PCT Application No. PCT/CN2024/087926, filed on Apr. 16, 2024, which is incorporated herein by reference in its entirety.

### TECHNICAL FIELD

The present disclosure generally relates to micro display technology, and more particularly, to a micro light emitting diode (LED) structure.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuitry back panel. Each pixel of the micro LED display panel is formed by one or more micro LEDs. The micro LED display panel can be a mono-color or multi-color panel. In particular, for a multi-color LED panel, each pixel may further include multiple sub-pixels formed by multiple micro LEDs, each of which corresponds to a different color. For example, three micro LEDs respectively corresponding to red, green, and blue colors may be superimposed to form one pixel. The different colors can be mixed to produce a broad array of colors.

Current micro LED technology faces several challenges, for example, to improve an effective illumination area within each pixel when a distance between the adjacent micro LEDs is determined.

### SUMMARY OF THE DISCLOSURE

Embodiments of the present disclosure provide a micro LED structure. The micro LED structure includes: a micro mesa comprising a bottom electrode, a PN junction structure, and a top electrode from bottom to top; and a micro lens formed on the micro mesa, wherein a top surface of the micro lens comprises a sub-micro lens array comprising a plurality of sub-micro lenses.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram of an example micro LED structure, according to some embodiments of the present disclosure.

FIG. 2 illustrates a structural diagram of an example micro mesa shown in FIG. 1, according to some embodiments of the present disclosure.

FIG. 3 illustrates a structural diagram of another example micro LED structure, according to some embodiments of the present disclosure.

FIG. 4 illustrates a structural diagram of another example micro LED structure, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED lens with coarsening structures to improve illumination performance.

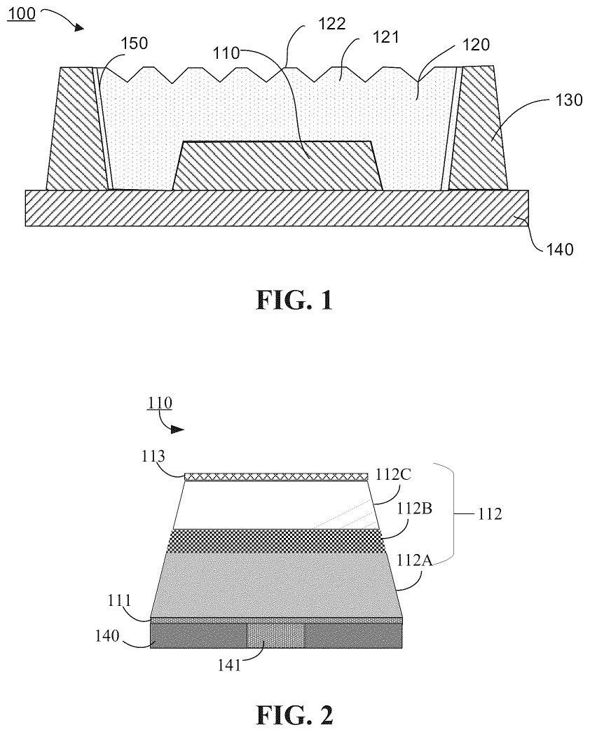

FIG. 1 illustrates a structural diagram of an example micro LED structure 100, according to some embodiments of the present disclosure. As shown in FIG. 1, micro LED structure 100 includes a micro mesa 110 and a micro lens 120 formed on micro mesa 110. Micro mesa 110 is configured to emit light, and micro lens 120 is configured to amplify and orient the light emitted from micro mesa 110. A top surface of micro lens 120 includes a sub-micro lens array including a plurality of sub-micro lenses 121. The plurality of sub-micro lenses 121 are provided on a top surface 122 of micro lens 120, and arranged in an array. In some embodiments, top surface 122 of micro lens 120 is hemispherical shape. In some embodiments, top surface 122 of micro lens 120 is round. In some embodiments, micro lens 120 covers a top surface and a sidewall surface of micro mesa 110.

With the sub-micro lens array on top surface 122 of micro lens 120, light crosstalk between adjacent micro LED structures 100 can be reduced.

In some embodiments, a material of micro lens 120 is SiO₂ or Si₃N₄. In some embodiments, the sub-micro lens array is a photonic crystal array. Using a material with higher refractivity for micro lens 120 can further reduce the light crosstalk.

Micro LED structure 100 further includes a contact pad 130 provided around micro mesa 110, and a gap formed between contact pad 130 and micro mesa 110. That is, contact pad 130 and micro mesa 110 do not contact each other. In some embodiments, micro lens 120 is filled in the gap. In some embodiments, micro lens 120 is in contact with contact pad 130 and micro mesa 110. A top of micro lens 120 is not lower than a top of contact pad 130. As shown in FIG. 1, in exemplary micro LED structure 100, a top of micro lens 120 is equal to a top of contact pad 130. Each sub-micro lens 121 has a tapered structure. Top surface 122 of sub-micro lens 121 is the top of micro lens 120. In some embodiments, a top view of micro lens 120 and micro mesa 110 are round, and a diameter of micro lens 120 is greater than 150% of a diameter of micro mesa 110. Micro lens 120 fully covers micro mesa 110, and a width of the gap between contact pad 130 and micro mesa 110 is greater than 50% of a diameter of micro mesa 110.

In some embodiments, micro LED structure 100 further includes a reflective structure 150 provided at a sidewall of contact pad 130. Reflective structure 150 faces a sidewall of micro mesa 110, thereby reflecting light with small incident angle emitted by micro mesa 110 to micro lens 120. With reflective structure 150, light emitting performance is improved.

Micro LED structure 100 further includes an integrated circuit (IC) backplane 140 provided at a bottom of micro mesa 110 and a bottom of contact pad 130. IC backplane 140 is bonded with the bottom of micro mesa 110.

FIG. 2 illustrates a structural diagram of micro mesa 110 shown in FIG. 1, according to some embodiments of the present disclosure. As shown in FIG. 2, micro mesa 110 further includes a bottom electrode 111, a PN junction structure 112, and a top electrode 113 from bottom to top. PN junction structure 112 further includes a first type epitaxial layer 112A, a light emitting layer 112B formed on first type epitaxial layer 112A, and a second type epitaxial layer 112C formed on light emitting layer 112B. In some embodiments, the first type is P type and the second type is N type. In some embodiments, the first type is N type and the second type is P type. In some embodiment, IC backplane 140 further includes a bottom pad 141 configured to connect to bottom electrode 111 of micro mesa 110.

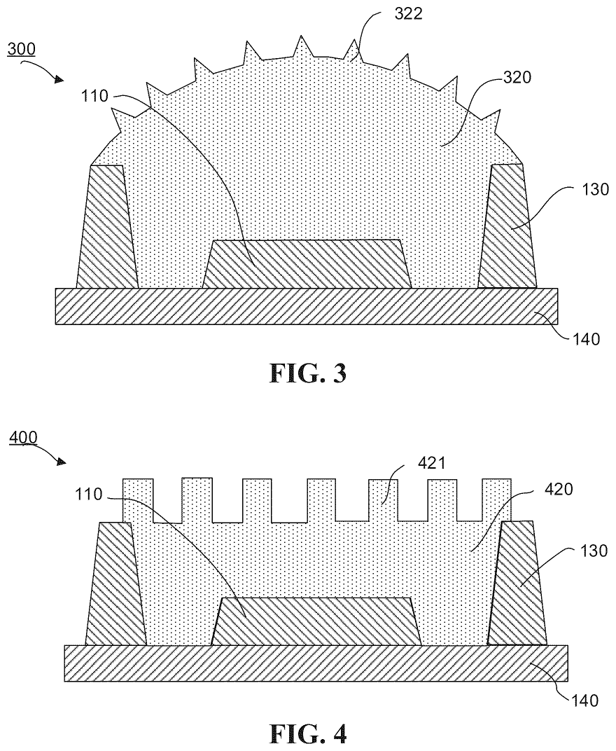

FIG. 3 illustrates a structural diagram of an example micro LED structure 300, according to some embodiments of the present disclosure. As shown in FIG. 3, micro LED structure 300 includes micro mesa 110 and contact pad 130 around micro mesa 110, as in micro LED structure 100. Micro LED structure 300 also includes a micro lens 320. A surface of micro lens 320 has a hemispherical shape. A top surface of micro lens 320 includes a sub-micro lens array including a plurality of sub-micro lenses 322 in a semi-spherical array. Micro lens 320 also covers a top surface of contact pad 130. A height of micro lens 320 is higher than a top of contact pad 130. In this example, each of sub-micro lenses 322 has a conical structure with a sharp tip.

FIG. 4 illustrates a structural diagram of an example micro LED structure 400, according to some embodiments of the present disclosure. As shown in FIG. 4, micro LED structure 400 includes micro mesa 110 and contact pad 130 around micro mesa 110, as in micro LED structure 100. Micro LED structure 400 also includes a micro lens 420. A surface of micro lens 420 is round, and a section view of the surface of micro lens 420 has a square wave shape. A top surface of micro lens 420 includes a sub micro lens array including a plurality of sub micro lenses 421. Each of sub-micro lenses 421 has a square mesa structure. Micro lens 420 covers a part of the top surface of contact pad 130.

Details about other structures of micro LED structures 300 and 400 are those described above with reference to FIG. 1 and FIG. 2, which will not be repeated herein.

Each micro LED structure herein (e.g., micro LED structure 100, 300, and 400) has a very small volume. The micro LED structure can be applied in a micro LED display panel. The light emitting area of the micro LED display panel is very small, such as 1 mm×1 mm, 3 mm×5 mm, etc. In some embodiments, the light emitting area is the area of an array of micro LED in the micro LED display panel. The micro LED display panel includes one or more micro LED structures that form a pixel array in which the micro LEDs are pixels, such as a 1600×1200, 680×480, or 1920×1080-pixel array. The diameter of each micro LED structure is in the range of about 200 nm to 2 μm. An IC backplane, e.g., IC backplane 140, is formed at the back surface of the micro LED array and is electrically connected with the micro LED array. The IC backplane acquires signals such as image data from outside via signal lines to control corresponding micro LEDs to emit light or not.

Different types of micro LED panels can be provided. For example, the resolution of a display panel can range typically from 8×8 to 3840×2160. Common display resolutions include QVGA (Quarter Video Graphics Array) with 320×240 resolution and an aspect ratio of 4:3, XGA (Extended Graphics Array) with 1024×768 resolution and an aspect ratio of 4:3, D (Definition) with 1280×720 resolution and an aspect ratio of 16:9, FHD (Full High Definition) with 1920×1080 resolution and an aspect ratio of 16:9, UHD (Ultra High Definition) with 3840×2160 resolution and an aspect ratio of 16:9, and 4K with 4096×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED structure, comprising:
a micro mesa comprising a bottom electrode, a PN junction structure, and a top electrode from bottom to top; and
a micro lens formed on the micro mesa, wherein a top surface of the micro lens comprises a sub-micro lens array comprising a plurality of sub-micro lenses.

2. The micro LED structure according to claim 1, further comprising a contact pad provided around the micro mesa, wherein a gap is formed between the contact pad and the micro mesa.

3. The micro LED structure according to claim 2, wherein a top of the micro lens is not lower than a top of the contact pad.

4. The micro LED structure according to claim 2, wherein the micro lens is filled in the gap between the contact pad and the micro mesa.

5. The micro LED structure according to claim 2, wherein the micro lens is in contact with the contact pad and the micro mesa.

6. The micro LED structure according to claim 1, wherein the sub-micro lens array is a semi-spherical array.

7. The micro LED structure according to claim 1, wherein the sub-micro lens array is a photonic crystal array.

8. The micro LED structure according to claim 1, wherein a material of the micro lens is SiO₂ or Si₃N₄.

9. The micro LED structure according to claim 2, further comprising an integrated circuit (IC) backplane provided at a bottom of the micro mesa and a bottom of the contact pad, wherein the IC backplane is bonded with the bottom of the micro mesa.

10. The micro LED structure according to claim 1, wherein the micro lens covers a top surface and a sidewall surface of the micro mesa.

11. The micro LED structure according to claim 2, wherein the micro lens covers a top surface and a sidewall surface of the mesa;
the micro LED structure further comprising an integrated circuit (IC) backplane formed at a bottom surface of the micro mesa and the bottom surface of the contact pad, the IC backplane bonded with the bottom of the micro mesa.

12. The micro LED structure according to claim 1, wherein the PN junction structure further comprises:
a first type epitaxial layer;
a light emitting layer formed on the first type epitaxial layer; and
a second type epitaxial layer formed on the light emitting layer; wherein the first type is P type and the second type is N type; or the first type is N type and the second type is P type.

13. The micro LED structure according to claim 1, wherein a top view of the micro lens and the micro mesa are round, and a diameter of the micro lens is greater than 150% of a diameter of the micro mesa.

14. The micro LED structure according to claim 2, further comprising a reflective structure provided at a sidewall of the contact pad facing the micro mesa.
